(19) United States
(12) Patent Application Publication
(10) Pub. No.: US 2006/0120054 A1
(43) Pub. Date: Jun. 8, 2006

(54) Electronics housing with integrated thermal dissipater

(75) Inventor: Ingo Buschke, Freiburg (DE)

Correspondence Address: BACON & THOMAS, PLLC, 625 SLATERS LANE, FOURTH FLOOR, ALEXANDRIA, VA, 22314, US

(73) Assignee: Endress & Hauser Gmbh & Co. KG, Maulburg (DE)

(21) Appl. No.: 10/522,785

(22) PCT Filed: Jul. 18, 2003
(86) PCT No.: PCT/EP03/07837

§ 371 Date: Sep. 6, 2005

(30) Foreign Application Priority Data
Jul. 31, 2002 (DE) 10235047.7

(51) Int. Cl. H05K 7/20

(52) U.S. Cl. 361/707; 361/720

(57) ABSTRACT

An electronics housing with a circuit board in the interior of the electronics housing, fitted with electronics components on at least one first surface, said first surface facing a first wall of the electronics housing and the interior is filled with a thermally conducting sealing mass, at least between the first surface of the circuit board and the first wall. According to the invention, local overheating on the external housing surfaces may be avoided whereby a planar heat dissipater is arranged in the sealing mass, between the circuit board and the first wall, which has a higher specific heat conductivity than the sealing mass, whereby inhomogeneous temperature distributions along the surfaces of the first wall are reduced.

The present invention relates to an electronics housing, especially an electronics housing for a measurement transmitter.

In the design of electronic devices, it is important that temperature peaks be largely avoided, in order to assure the reliability of the electronic circuit. Especially in explosion-protected applications, it must be assured that heat given-off by electronic components is carried away, such that ignition temperature is never reached on any surface of a device.

The state of the art discloses, especially, printed heat-sinks on circuit boards. This subject is reviewed by Kramer et al. in Paper No. 144 of the EPC Conference on Nov. 11, 1999, in Munich, Germany. However heat paths printed on a circuit board have a surface area requirement which limits the integration of electric and/or electronic components on the circuit board.

European Patent No. 0 920 789 B1 discloses a heat sink. This involves an essentially planar, metal heat sink, which is arranged parallel to the circuit board between two, thin, slightly separated layers of electrically insulating and thermally conducting, potting compound. The metal heat sink continues in its edge region in the form of a heat conducting tongue, which is led out of the potting compound and connected with a sufficiently large, thermal mass, which is arranged laterally of the circuit board, whereby the waste heat is led away, parallel to the circuit board. For the secure anchoring of the metal heat sink in the thin layers of potting compound, the metal heat sink has pores, through which the potting compound penetrates. The described device is disadvantageous in the aspect that the cross section of the heat sink perpendicular to the direction of heat flow is very small and additionally lessened by the pores. Additionally, the construction of the heat-conducting tongue and its connection to the thermal mass are very complex.

It is therefore an object of the present invention to provide an electronics housing, which overcomes the described disadvantages.

Basis for the solution of the invention is the consideration that it is not the reduction of the amount of heat given-off via a housing wall which is important, but, instead, the spreading of the heat sufficiently homogeneously over the surface of the housing wall.

The object is achieved according to the invention by the device as defined in independent claim 1.

The device of the invention includes: an electronics housing, which defines an internal space; at least one circuit board, which is arranged in the internal space and which is populated, at least on a first surface, with electronic components, with the first surface facing a first wall of the electronics housing and the internal space being filled with a potting compound, at least between the first surface of the circuit board and the first wall, whereby heat given-off by the electronic components can be led away to the first wall; with there being embedded in the potting compound, between the circuit board and the first wall, an areal heat spreader, which has a front side facing the first wall and a rear side facing the circuit board, and which has a thermal conductivity which is greater than that of the potting compound, whereby inhomogeneous temperature distributions along the surface of the first wall are markedly reduced.

The heat spreader can be, for example, a thin metal layer, sheet or plate, for example of copper. The thickness of the metal sheet is determined by one skilled in the art from the amount of heat to be spread. In most cases, thicknesses of not more than about 1 mm, preferably not more than 0.4 mm, especially preferably between 0.05 mm and 0.2 mm are sufficient.

The heat spreader spans, preferably, at least the surface area of the circuit board in which those components are arranged, which produce significant portions of the evolved heat.

To the extent that the circuit board and first housing wall are planar, a planar heat spreader is preferred, which is arranged parallel to the circuit board and to the housing wall. In principle, also a structured surface with beam-shaped wave trains makes sense, due to the advantage of a possible, marked surface area enlargement. If the housing wall exhibits a curvature, then the heat spreader can either be planar or curved, with the degree of curvature preferably being not stronger than the curvature of the housing wall.

Silgel is currently preferred as potting compound. However, other potting compounds are suitable, which are electrically insulating and have a sufficient heat conductivity.

The electronics housing can be, in particular, the housing of a measurement transmitter, such as is used, for example, in industrial process measurement technology. The invention is especially suited for housings in explosion-protected applications, since, in such case, it is absolutely necessary that the temperature of the entire surface of the housing remain below critical limit values.

Further advantages and features of the invention will be evident on the basis of the dependent claims, the following description of an example of an embodiment, and the drawings, the figures of which show as follows:

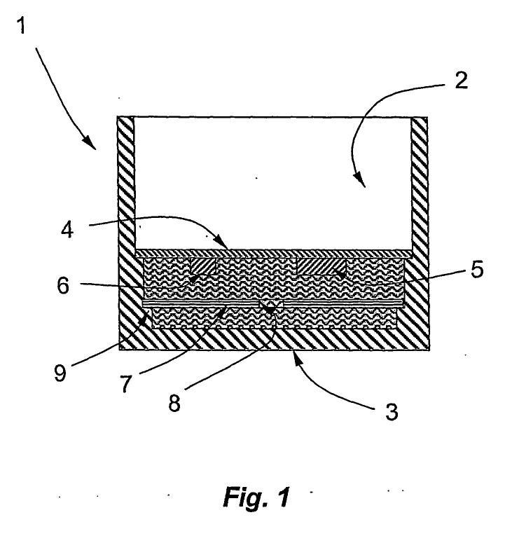

FIG. 1 a sectional view of an electronics housing of the invention; and

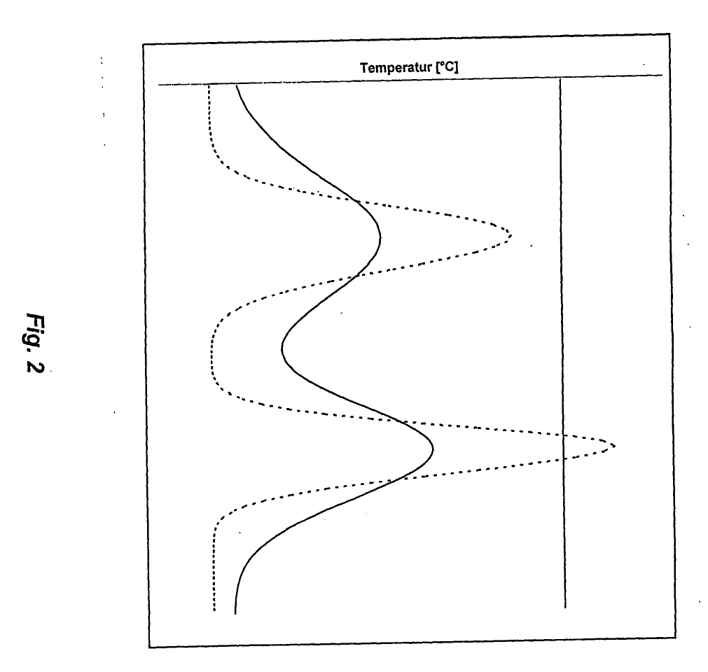

FIG. 2 temperature distribution on the surface of an electronics housing of the invention, compared with an electronics housing of the state of the art.

The measurement transmitter housing 1 shown in FIG. 1 includes an internal space 2, in which a circuit board 4 is arranged parallel to a first wall 3 of the housing 1. The first wall can, for example, be an end face of a cylindrical housing 1. On a first surface of the circuit board 4 facing the first wall, electronic or electric components 5, 6 are arranged, which give off heat when operating. This heat must be led away, in order to prevent an overheating of the electronic components 5, 6.

To this end, the internal space 2 is filled with a potting compound 10, preferably Silgel, at least in the section between the circuit board 4 and the first wall 3. Embedded in the potting compound is a heat spreader 7, which is arranged essentially parallel to the circuit board 4. The position of the heat spreader 7 between the circuit board and the first wall 3 is determined in this form of embodiment by stops 9, against which the heat spreader bears in its edge region.

The heat spreader 7 is preferably a metal layer, especially a metal foil, sheet or plate. In a currently preferred form of embodiment, a copper sheet of 0.2 mm thickness is employed.

The optional opening 8 in the heat spreader 7 enables penetration of the potting compound, which improves the mechanical anchoring of the heat spreader 7.

The effect of the heat spreader will now be explained on the basis of the diagram in FIG. 2, which shows a plot of temperature on the external surface of the housing wall 3 along a line whose projection onto the plane of the circuit board cuts across the electronic components 5, 6. The dashed line shows the behavior of temperature in the absence of a heat spreader in the potting compound and the continuous line shows the behavior of temperature when a heat spreader is present in the potting compound. The heat spreader broadens the local maxima of temperature, and the peak values are markedly lowered, so that temperatures are kept well below critical limit values. Values are not shown on the axes, since the exact values of the temperature lines will depend, for instance, on the detailed geometries of particular arrangements. In terms of a guideline, the peak temperature can be lowered from around 75° C., down to 45° C.

In this way, marked factors of safety relative to the critical temperatures of explosion-endangered processes can be achieved, this providing increased reserves of safety even in the case of the overheating of components accompanying their failure.

1-8. (canceled)

9. A device, comprising:
an electronics housing, which defines a first wall and an internal space;
at least one circuit board, which is arranged in the internal space and which is populated at least on a first surface with electronic components, with said first surface facing said first wall and said internal space being filled with a potting compound at least between said first surface and said first wall, whereby heat given-off by said electronic components can be led-away to said first wall;
an area head spreader
embedded in the potting compound between said at least one circuit board and said first wall has a front face and a rear face, which faces said first wall with its front face and said circuit board with its rear face, and which has a greater thermal conductivity than the potting compound, whereby inhomogeneous temperature distributions over the surface of said first wall can be reduced.

10. The device as claimed in claim 9, wherein:
said heat spreader comprises a metal or ceramic layer, foil.

11. The device as claimed in claim 10, wherein:
said heat spreader comprises copper or aluminum nitride.

12. The device as claimed in claim 10, wherein;
said heat spreader has a thickness of the metal or ceramic sheet of not more than 1 mm, preferably not more than 0.4 mm, and especially preferably between 0.05 mm and 0.2 mm.

13. The device as claimed in claim 10, wherein:
said heat spreader is essentially planar.

14. The device as claimed in claim 10, wherein:
said first wall is curved, and wherein said heat spreader is either planar or curved, and its degree of curvature is not greater than the curvature of said first wall.

15. The device as claimed in claim 10, wherein:
said heat spreader exhibits a wave pattern, especially a beam-shaped wave pattern.

16. The device as claimed in claim 10, wherein:
the device is a measurement transmitter, especially for explosion-protected applications.
